(19) United States
(12) Patent Application Publication
(10) Pub. No.: US 2015/0124234 A1
(43) Pub. Date: May 7, 2015

(54) SUBSTRATE HOLDER, LITHOGRAPHIC APPARATUS, AND DEVICE MANUFACTURING METHOD

(71) Applicant: ASML Netherlands B.V., Veldhoven (NL)

(72) Inventors: Raymond Wilhelmus Louis Lafarre, Helmond (NL); Nina Vladimirovna Dziomkina, Eindhoven (NL); Yogesh Pramod Karade, Eindhoven (NL); Elisabeth Corinne Rodenburg, Heeze (NL); Harmeet Singh, Fremont, CA (US)

(73) Assignee: ASML Netherlands B.V., Veldhoven (NL)

(21) Appl. No.: 14/390,973

(22) PCT Filed: Mar. 19, 2013
(86) PCT No.: PCT/EP2013/055597

§ 371 Date: Oct. 6, 2014

Related U.S. Application Data
(60) Provisional application No. 61/635,754, filed on Apr. 19, 2012.

(51) Int. Cl. G03F 7/20

(52) U.S. Cl. CPC G03F 7/70733
USPC 355/72

(57) ABSTRACT

A substrate holder for use in a lithographic apparatus, the substrate holder including: a main body having a surface; a plurality of burls projecting from the surface and having end surfaces to support a substrate; and a thin film stack on the main body surface and forming an electric component, the thin film stack having a conductive layer configured to distribute electrical charge substantially uniformly throughout a plane of the stack in which the conductive layer is positioned.

### CROSS-REFERENCE TO RELATED APPLICATIONS

This application claims the benefit of US provisional application 61/635,754, which was filed on Apr. 19, 2012 and which is incorporated herein in its entirety by reference.

### FIELD

The present invention relates to a substrate holder, a lithographic apparatus, and a device manufacturing method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

It has been proposed to immerse the substrate in the lithographic projection apparatus in a liquid having a relatively high refractive index, e.g. water, so as to fill a space between the final element of the projection system and the substrate. In an embodiment, the liquid is distilled water, although another liquid can be used. An embodiment of the present invention will be described with reference to liquid. However, another fluid may be suitable, particularly a wetting fluid, an incompressible fluid and/or a fluid with higher refractive index than air, desirably a higher refractive index than water. Fluids excluding gases are particularly desirable. The point of this is to enable imaging of smaller features since the exposure radiation will have a shorter wavelength in the liquid. (The effect of the liquid may also be regarded as increasing the effective numerical aperture (NA) of the system and also increasing the depth of focus.) Other immersion liquids have been proposed, including water with solid particles (e.g. quartz) suspended therein, or a liquid with a nano-particle suspension (e.g. particles with a maximum dimension of up to 10 nm). The suspended particles may or may not have a similar or the same refractive index as the liquid in which they are suspended. Other liquids which may be suitable include a hydrocarbon, such as an aromatic, a fluorohydrocarbon, and/or an aqueous solution.

### SUMMARY

In a conventional lithography apparatus, the substrate to be exposed may be supported by a substrate holder which in turn is supported by a substrate table. The substrate holder is often a flat rigid disc corresponding in size and shape to the substrate (although it may have a different size or shape). It has an array of projections, referred to as burls or pimples, projecting from at least one side. In an embodiment, the substrate holder has an array of projections on two opposite sides. In this case, when the substrate holder is placed on the substrate table, the main body of the substrate holder is held a small distance above the substrate table while the ends of the burls on one side of the substrate holder lie on the surface of the substrate table. Similarly, when the substrate rests on the top of the burls on the opposite side of the substrate holder, the substrate is spaced apart from the main body of the substrate holder. One purpose of this is to help prevent a particle (i.e. a contaminating particle such as a dust particle) which might be present on either the substrate table or substrate holder from distorting the substrate holder or the substrate. Since the total surface area of the burls is only a small fraction of the total area of the substrate or substrate holder, it is highly probable that any particle will lie between burls and its presence will have no effect.

Due to the high accelerations experienced by the substrate in use of a high-throughput lithographic apparatus, it is not sufficient to allow the substrate simply to rest on the burls of the substrate holder. It is clamped in place. Two methods of clamping the substrate in place are known—vacuum clamping and electrostatic clamping. In vacuum clamping, the space between the substrate holder and substrate and optionally between the substrate table and substrate holder are partially evacuated so that the substrate is held in place by the higher pressure of gas or liquid above it. Vacuum clamping however may not be feasible where the beam path and/or the environment near the substrate or substrate holder is kept at a low or very low pressure, e.g. for extreme ultraviolet (EUV) radiation lithography. In this case, it may not be possible to develop a sufficiently large pressure difference across the substrate (or substrate holder) to clamp it. Electrostatic clamping can therefore be used in such a circumstance (or in other circumstances). In electrostatic clamping, an electrode provided on the substrate table and/or substrate holder is raised to a high potential, e.g. 10 to 5000 V, and electrostatic forces attract the substrate. Thus another purpose of the burls is to space the substrate, substrate holder and substrate table apart in order to enable electrostatic clamping.

Temperature control over the substrate surface is significant, in particular in immersion systems which are sensitive to temperature variation due to liquid (e.g. water) evaporation effects. Evaporation of liquid removes heat from the substrate, causing temperature variation. The temperature variation may lead to thermal stress in the substrate which eventually may contribute to overlay error. To improve accuracy of temperature control, real time local measurement of the temperature combined with active heating is desired. Such a measurement and heating system is integrated into the system, e.g. in the substrate holder (i.e. the object that directly supports a substrate) and/or substrate table (e.g., a mirror block of a substrate stage, i.e. the object that supports the substrate holder and provides the upper surface surrounding the substrate holder). A thin-film stack can be used to make a structure that can both measure and heat such a structure and offers the opportunity for integration into the substrate holder and/or table.

It is desirable, for example, to provide a substrate table or substrate holder on which one or more electronic or electric components, such as one or more thin-film components, are formed.

According to an aspect of the invention, there is provided a substrate holder for use in a lithographic apparatus, the substrate holder comprising: a main body having a surface; a plurality of burls projecting from the surface and having end surfaces to support a substrate; and a thin film stack on the main body surface and forming an electric component, the thin film stack comprising a conductive layer configured to distribute electrical charge substantially uniformly throughout a plane of the stack in which the conductive layer is positioned.

According to an aspect of the present invention, there is provided a device manufacturing method using a lithographic apparatus, the method comprising: projecting a beam patterned by a patterning device onto a substrate while holding the substrate in or on a substrate holder, the substrate holder comprising: a main body having a surface; a plurality of burls projecting from the surface and having end surfaces to support a substrate; and a thin film stack on the main body surface and forming an electric component, the thin film stack comprising a conductive layer configured to distribute electrical charge substantially uniformly throughout a plane of the stack in which the conductive layer is positioned.

According to an aspect of the present invention, there is provided a substrate holder for use in a lithographic apparatus, the substrate holder comprising: a main body having a surface; a plurality of burls projecting from the surface and having end surfaces to support a substrate; and a thin film stack on the main body surface and forming an electric component, the thin film stack comprising a conductive layer which extends over substantially the whole area, in plan, of the stack.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIGS. 2 and 3 depict a liquid supply system for use in a lithographic projection apparatus;

FIG. 4 depicts a further liquid supply system for use in a lithographic projection apparatus;

FIG. 5 depicts, in cross-section, a barrier member which may be used in an embodiment of the present invention as an immersion liquid supply system;

FIG. 6 depicts a lithographic apparatus according to an embodiment of the invention;

FIG. 7 is a more detailed view of the apparatus 4100;

FIG. 8 is a more detailed view of the source collector apparatus SO of the apparatus of FIGS. 6 and 7;

FIG. 9 depicts in cross-section a substrate table and a substrate holder according to an embodiment of the invention; and

FIGS. 10 to 15 depict thin-film stacks according to embodiments of the invention.

### DETAILED DESCRIPTION

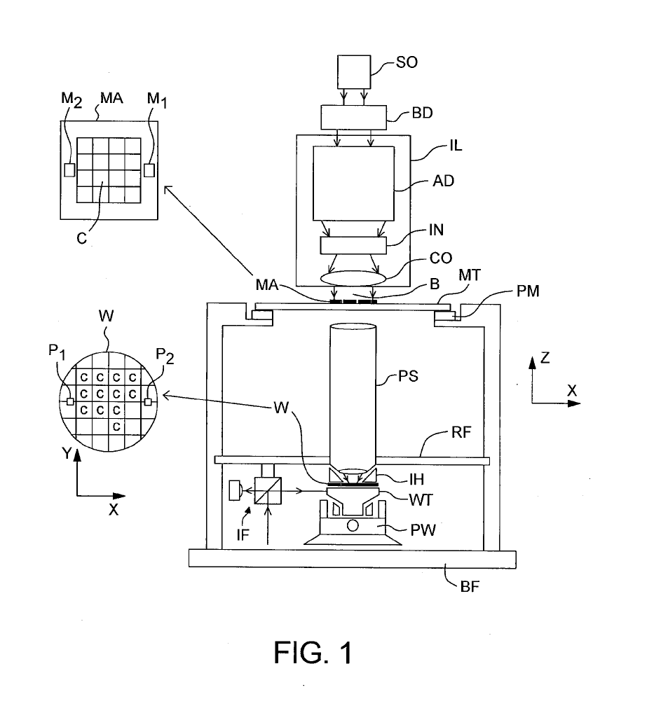

FIG. 1 schematically depicts a lithographic apparatus according to one embodiment of the invention. The apparatus comprises:
an illumination system (illuminator) IL configured to condition a radiation beam B (e.g. UV radiation, DUV radiation or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WT constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device. The support structure MT holds the patterning device in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device. The support structure MT may be a frame or a table, for example, which may be fixed or movable as required. The support structure MT may ensure that the patterning device is at a desired position, for example with respect to the projection system. Any use of the terms “reticle” or “mask” herein may be considered synonymous with the more general term “patterning device”.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The terms “projection system” used herein should be broadly interpreted as encompassing any type of system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two or more substrate support structures, such as substrate stages or substrate tables, and/or two or more support structures for patterning devices. In an apparatus with multiple substrate stages, all the substrate stages can be equivalent and interchangeable. In an embodiment, at least one of the multiple substrate stages is particularly adapted for exposure steps and at least one of the multiple substrate stages is particularly adapted for measurement or preparatory steps. In an embodiment of the invention one or more of the multiple substrate stages is replaced by a measurement stage. A measurement stage includes at least part one or more sensor systems such as a sensor detector and/or target of the sensor system but does not support a substrate. The measurement stage is positionable in the projection beam in place of a substrate stage or a support structure for a patterning device. In such apparatus the additional stages may be used in parallel, or preparatory steps may be carried out on one or more stages while one or more other stages are being used for exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AM configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section. Similar to the source SO, the illuminator IL may or may not be considered to form part of the lithographic apparatus. For example, the illuminator IL may be an integral part of the lithographic apparatus or may be a separate entity from the lithographic apparatus. In the latter case, the lithographic apparatus may be configured to allow the illuminator IL to be mounted thereon. Optionally, the illuminator IL is detachable and may be separately provided (for example, by the lithographic apparatus manufacturer or another supplier).

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. Substrate W is held on the substrate table WT by a substrate holder according to an embodiment of the present invention and described further below. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

In many lithographic apparatuses, a fluid, in particular a liquid, is provided between the final element of the projection system using a liquid supply system IH to enable imaging of smaller features and/or increase the effective NA of the apparatus. An embodiment of the invention is described further below with reference to such an immersion apparatus, but may equally be embodied in a non-immersion apparatus. Arrangements to provide liquid between a final element of the projection system and the substrate can be classed into at least two general categories. These are the bath type arrangement and the so called localized immersion system. In the bath type arrangement substantially the whole of the substrate and optionally part of the substrate table is submersed in a bath of liquid. The localized immersion system uses a liquid supply system in which liquid is only provided to a localized area of the substrate. In the latter category, the space filled by liquid is smaller in plan than the top surface of the substrate and the area filled with liquid remains substantially stationary relative to the projection system while the substrate moves underneath that area. Another arrangement, to which an embodiment of the invention is directed, is the all wet solution in which the liquid is unconfined. In this arrangement substantially the whole top surface of the substrate and all or part of the substrate table is covered in immersion liquid. The depth of the liquid covering at least the substrate is small. The liquid may be a film, such as a thin-film, of liquid on the substrate.

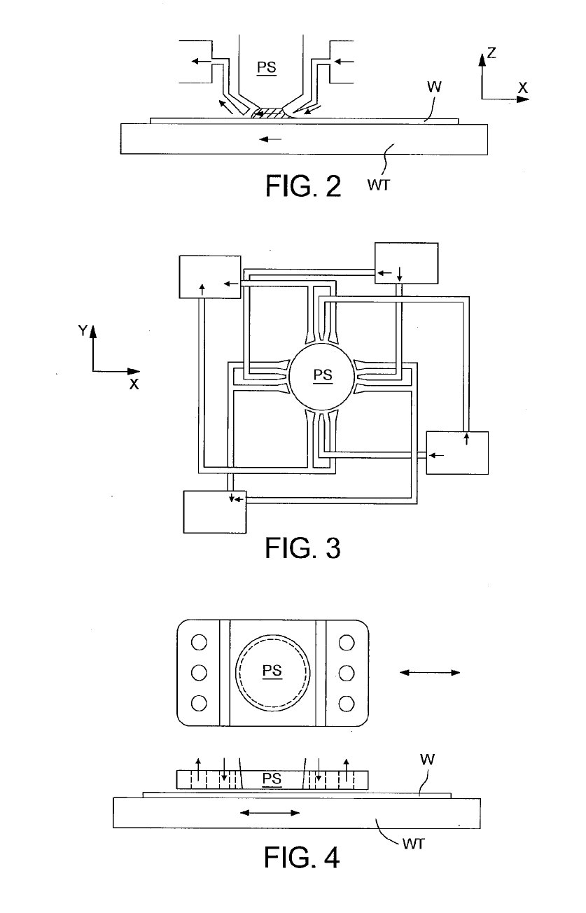

Four different types of localized liquid supply systems are illustrated in FIGS. 2 to 5. Any of the liquid supply devices of FIGS. 2 to 5 may be used in an unconfined system; however, sealing features are not present, are not activated, are not as efficient as normal or are otherwise ineffective to seal liquid to only the localized area.

One of the arrangements proposed for a localized immersion system is for a liquid supply system to provide liquid on only a localized area of the substrate and in between the final element of the projection system and the substrate using a liquid confinement system (the substrate generally has a larger surface area than the final element of the projection system). One way which has been proposed to arrange for this is disclosed in PCT patent application publication no. WO 99/49504. As illustrated in FIGS. 2 and 3, liquid is supplied by at least one inlet onto the substrate, desirably along the direction of movement of the substrate relative to the final element, and is removed by at least one outlet after having passed under the projection system. That is, as the substrate is scanned beneath the element in a −X direction, liquid is supplied at the +X side of the element and taken up at the −X side.

FIG. 2 shows the arrangement schematically in which liquid is supplied via inlet and is taken up on the other side of the element by outlet which is connected to a low pressure source. The arrows above the substrate W illustrate the direction of liquid flow, and the arrow below the substrate W illustrates the direction of movement of the substrate table. In the illustration of FIG. 2 the liquid is supplied along the direction of movement of the substrate relative to the final element, though this does not need to be the case. Various orientations and numbers of in- and out-lets positioned around the final element are possible, one example is illustrated in FIG. 3 in which four sets of an inlet with an outlet on either side are provided in a regular pattern around the final element. Arrows in liquid supply and liquid recovery devices indicate the direction of liquid flow.

A further immersion lithography solution with a localized liquid supply system is shown in FIG. 4. Liquid is supplied by two groove inlets on either side of the projection system PS and is removed by a plurality of discrete outlets arranged radially outwardly of the inlets. The inlets and outlets can be arranged in a plate with a hole in its center and through which the projection beam is projected. Liquid is supplied by one groove inlet on one side of the projection system PS and removed by a plurality of discrete outlets on the other side of the projection system PS, causing a flow of a thin-film of liquid between the projection system PS and the substrate W. The choice of which combination of inlet and outlets to use can depend on the direction of movement of the substrate W (the other combination of inlet and outlets being inactive). In the cross-sectional view of FIG. 4, arrows illustrate the direction of liquid flow in to inlets and out of outlets.

Another arrangement which has been proposed is to provide the liquid supply system with a liquid confinement member which extends along at least a part of a boundary of the space between the final element of the projection system and the substrate table. Such an arrangement is illustrated in FIG. 5. The liquid confinement member is substantially stationary relative to the projection system in the XY plane, though there may be some relative movement in the Z direction (in the direction of the optical axis). A seal is formed between the liquid confinement member and the surface of the substrate. In an embodiment, a seal is formed between the liquid confinement member and the surface of the substrate and may be a contactless seal such as a gas seal. Such a system is disclosed in United States patent application publication no. US 2004-0207824.

The fluid handling structure 12 includes a liquid confinement member and at least partly contains liquid in the space 11 between a final element of the projection system PS and the substrate W. A contactless seal 16 to the substrate W may be formed around the image field of the projection system so that liquid is confined within the space between the substrate W surface and the final element of the projection system PS. The space is at least partly formed by the fluid handling structure 12 positioned below and surrounding the final element of the projection system PS. Liquid is brought into the space below the projection system and within the fluid handling structure 12 by liquid inlet 13. The liquid may be removed by liquid outlet 13. The fluid handling structure 12 may extend a little above the final element of the projection system. The liquid level rises above the final element so that a buffer of liquid is provided. In an embodiment, the fluid handling structure 12 has an inner periphery that at the upper end closely conforms to the shape of the projection system or the final element thereof and may, e.g., be round. At the bottom, the inner periphery closely conforms to the shape of the image field, e.g., rectangular, though this need not be the case.

In an embodiment, the liquid is contained in the space 11 by a gas seal 16 which, during use, is formed between the bottom of the fluid handling structure 12 and the surface of the substrate W. The gas seal is formed by gas, e.g. air, synthetic air, N₂ or another inert gas. The gas in the gas seal is provided under pressure via inlet 15 to the gap between fluid handling structure 12 and substrate W. The gas is extracted via outlet 14. The overpressure on the gas inlet 15, vacuum level on the outlet 14 and geometry of the gap are arranged so that there is a high-velocity gas flow 16 inwardly that confines the liquid. The force of the gas on the liquid between the fluid handling structure 12 and the substrate W contains the liquid in a space 11. The inlets/outlets may be annular grooves which surround the space 11. The annular grooves may be continuous or discontinuous. The flow of gas 16 is effective to contain the liquid in the space 11. Such a system is disclosed in United States patent application publication no. US 2004-0207824.

The example of FIG. 5 is a localized area arrangement in which liquid is only provided to a localized area of the top surface of the substrate W at any one time. Other arrangements are possible, including fluid handling systems which make use of a single phase extractor or a two phase extractor as disclosed, for example, in United States patent application publication no US 2006-0038968.

Another arrangement which is possible is one which works on a gas drag principle. The so-called gas drag principle has been described, for example, in United States patent application publication nos. US 2008-0212046, US 2009-0279060, and US 2009-0279062. In that system the extraction holes are arranged in a shape which desirably has a corner. The corner may be aligned with the stepping or scanning directions. This reduces the force on the meniscus between two openings in the surface of the fluid handing structure for a given speed in the step or scan direction compared to a fluid handling structure having two outlets aligned perpendicular to the direction of scan.

Also disclosed in US 2008-0212046 is a gas knife positioned radially outside the main liquid retrieval feature. The gas knife traps any liquid which gets past the main liquid retrieval feature. Such a gas knife may be present in a so called gas drag principle arrangement (as disclosed in US 2008-0212046), in a single or two phase extractor arrangement (such as disclosed in United States patent application publication no. US 2009-0262318) or any other arrangement.

Many other types of liquid supply system are possible. The present invention is neither limited to any particular type of liquid supply system, nor to immersion lithography. The invention may be applied equally in any lithography. In an EUV lithography apparatus, the beam path is substantially evacuated and immersion arrangements described above are not used.

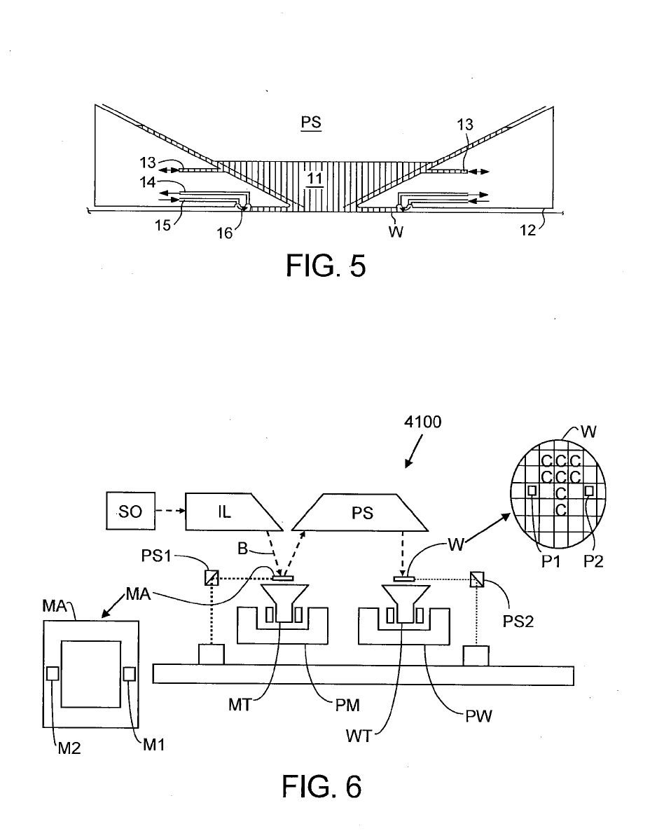

FIG. 6 schematically depicts an EUV lithographic apparatus 4100 including a source collector apparatus SO. The apparatus comprises:
an illumination system (illuminator) EIL configured to condition a radiation beam B (e.g. EUV radiation);
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist-coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

These basic components of the EUV lithographic apparatus are similar in function to the corresponding components of the lithographic apparatus of FIG. 1. The description below mainly covers areas of difference and duplicative description of aspects of the components that are the same is omitted.

In an EUV lithographic apparatus, it is desirable to use a vacuum or low pressure environment since gases can absorb too much radiation. A vacuum environment can therefore be provided to the whole beam path with the aid of a vacuum wall and one or more vacuum pumps.

Referring to FIG. 6, the EUV illuminator EIL receives an extreme ultra violet radiation beam from the source collector apparatus SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the desired line-emitting element, with a laser beam. The source collector apparatus SO may be part of an EUV radiation system including a laser, not shown in FIG. 6, to provide the laser beam exciting the fuel. The resulting plasma emits output radiation, e.g., EUV radiation, which is collected using a radiation collector, disposed in the source collector apparatus. The laser and the source collector apparatus may be separate entities, for example when a CO₂ laser is used to provide the laser beam for fuel excitation.

In such cases, the laser is not considered to form part of the lithographic apparatus and the radiation beam is passed from the laser to the source collector apparatus with the aid of a beam delivery system comprising, for example, suitable directing mirrors and/or a beam expander. In other cases the source may be an integral part of the source collector apparatus, for example when the source is a discharge-produced plasma EUV generator, often termed as a DPP source.

The EUV illuminator EIL may comprise an adjuster to adjust the angular intensity distribution of the radiation beam EB. Generally, at least the outer and/or inner radial extent (commonly referred to as σ-outer and σ-inner, respectively) of the intensity distribution in a pupil plane of the illuminator can be adjusted. In addition, the EUV illuminator EIL may comprise various other components, such as facetted field and pupil mirror devices. The EUV illuminator EIL may be used to condition the radiation beam EB, to have a desired uniformity and intensity distribution in its cross section.

The radiation beam EB is incident on the patterning device (e.g., mask) MA, which is held on the support structure (e.g., mask table) MT, and is patterned by the patterning device. After being reflected from the patterning device (e.g. mask) MA, the radiation beam EB passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam EB. Similarly, the first positioner PM and another position sensor PS1 can be used to accurately position the patterning device (e.g. mask) MA with respect to the path of the radiation beam EB. Patterning device (e.g. mask) MA and substrate W may be aligned using mask alignment marks M1, M2 and substrate alignment marks P1, P2.

The depicted apparatus could be used the same modes as the apparatus of FIG. 1.

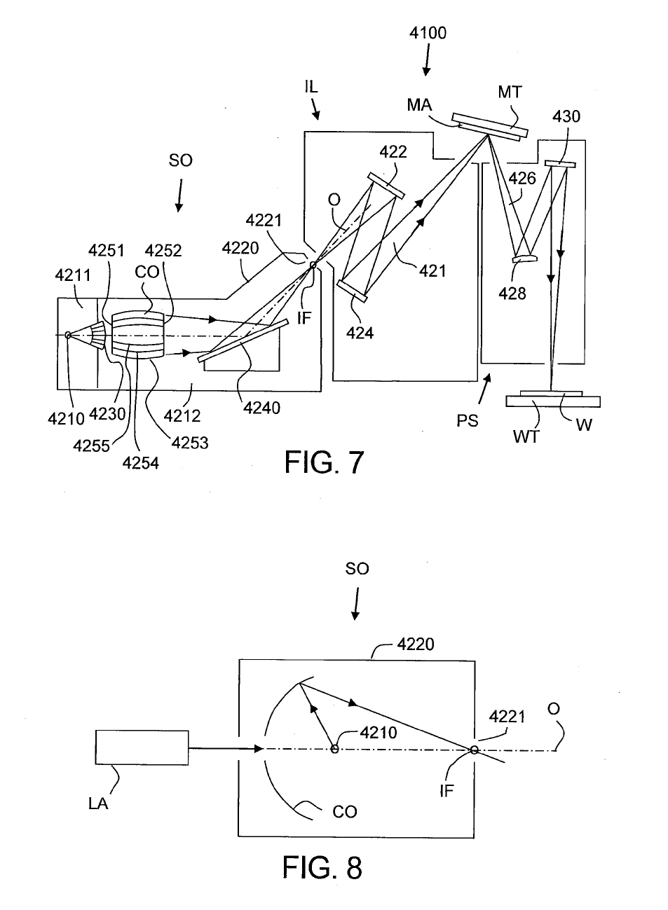

FIG. 7 shows the EUV apparatus 4100 in more detail, including the source collector apparatus SO, the EUV illumination system EIL, and the projection system PS. The source collector apparatus SO is constructed and arranged such that a vacuum environment can be maintained in an enclosing structure 4220 of the source collector apparatus SO. An EUV radiation emitting plasma 4210 may be formed by a discharge produced plasma source. EUV radiation may be produced by a gas or vapor, for example Xe gas, Li vapor or Sn vapor in which the plasma 4210 is created to emit radiation in the EUV range of the electromagnetic spectrum. The plasma 4210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the plasma 4210 is passed from a source chamber 4211 into a collector chamber 4212 via an optional gas barrier and/or contaminant trap 4230 (in some cases also referred to as contaminant barrier or foil trap) which is positioned in or behind an opening in source chamber 4211. The contaminant trap 4230 may include a channel structure. Contamination trap 4230 may also include a gas barrier or a combination of a gas barrier and a channel structure. The contaminant trap or contaminant barrier 4230 further indicated herein at least includes a channel structure, as known in the art.

The collector chamber 4212 may include a radiation collector CO which may be a so-called grazing incidence collector. Radiation collector CO has an upstream radiation collector side 4251 and a downstream radiation collector side 4252. Radiation that traverses collector CO can be reflected by a grating spectral filter 4240 to be focused in a virtual source point IF. The virtual source point IF is commonly referred to as the intermediate focus, and the source collector apparatus is arranged such that the intermediate focus IF is located at or near an opening 4221 in the enclosing structure 4220. The virtual source point IF is an image of the radiation emitting plasma 4210.

Subsequently the radiation traverses the illumination system IL, which may include a facetted field mirror device 422 and a facetted pupil mirror device 424 arranged to provide a desired angular distribution of the radiation beam 421, at the patterning device MA, as well as a desired uniformity of radiation intensity at the patterning device MA. Upon reflection of the beam of radiation 421 at the patterning device MA, held by the support structure MT, a patterned beam 426 is formed and the patterned beam 426 is imaged by the projection system PS via reflective elements 428, 430 onto a substrate W held by the substrate stage or substrate table WT.

More elements than shown may generally be present in illumination optics unit IL and projection system PS. The grating spectral filter 4240 may optionally be present, depending upon the type of lithographic apparatus. There may be more mirrors present than those shown in the Figures, for example there may be from 1 to 6 additional reflective elements present in the projection system PS than shown in FIG. 7.

Collector optic CO, as illustrated in FIG. 7, is depicted as a nested collector with grazing incidence reflectors 4253, 4254 and 4255, just as an example of a collector (or collector mirror). The grazing incidence reflectors 4253, 4254 and 4255 are disposed axially symmetric around an optical axis O and a collector optic CO of this type is preferably used in combination with a discharge produced plasma source, often called a DPP source.

Alternatively, the source collector apparatus SO may be part of an LPP radiation system as shown in FIG. 8. A laser LA is arranged to deposit laser energy into a fuel, such as xenon (Xe), tin (Sn) or lithium (Li), creating the highly ionized plasma 4210 with electron temperatures of several 10's of eV. The energetic radiation generated during de-excitation and recombination of these ions is emitted from the plasma, collected by a near normal incidence collector optic CO and focused onto the opening 4221 in the enclosing structure 4220.

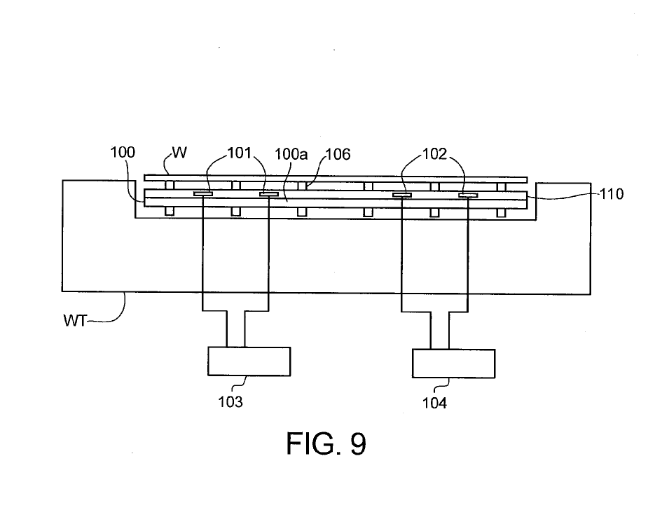

FIG. 9 depicts a substrate holder according to an embodiment of the invention. It may be held within a recess in substrate table WT and supports a substrate W. The main body of the substrate holder 100 has the form of a flat plate, for example a disc substantially corresponding in shape and size to the substrate W. At least on a top side, in an embodiment on both sides, the substrate holder has projections 106, commonly referred to as burls. In an embodiment, the substrate holder is an integral part of the substrate table and does not have burls on the lower surface. The burls are not shown to scale in FIG. 9.

The substrate holder surface may, for example, be formed from SiC, SiSiC, Zerodur lithium aluminosilicate glass-ceramic, cordierite, quartz or some other suitable ceramic or glass-ceramic material. The substrate holder 100 can be manufactured by selectively removing material from a solid disc of the relevant material so as to leave the projecting burls. A suitable technique for removing material include electrical discharge machining (EDM), etching and/or laser ablation. The technique may leave a rough surface, e.g. having a roughness value Ra of the order of several microns. The minimum roughness achievable with these removal techniques can derive from the material properties. For example, in the case of a two-phase material such as SiSiC, the minimum roughness achievable is determined by the grain size of the two-phase material. Such residual roughness causes difficulty in forming an electrical component, especially a thin film component on the surface, and unreliability in such a component. It is believed that these problems may arise because the roughness causes one or more gaps and/or cracks in a thin layer coated or grown on the substrate holder to form the electronic component. Thin film components may have layer thicknesses in the range of from about 2 nm to about 50 μm and may be formed by a process including chemical vapor deposition, physical vapor deposition (e.g. sputtering), dip coating, spin coating and/or spray coating.

In a practical embodiment, there can be many thousands of burls, e.g. more than 10,000 or more than 40,000, distributed across a substrate holder, e.g., of width (e.g., diameter) 200 mm, 300 mm or 450 mm. The tips of the burls have a small area, e.g. less than 1 mm². Thus the total area of all of the burls on one side of the substrate holder 100 is less than about 10%, e.g. 1-3% of the total area of the total surface area of the substrate holder. Because of the burl arrangement, there is a high probability that any particle that might lie on the surface of the substrate, substrate holder or substrate table will fall between burls and will not therefore result in a deformation of the substrate or substrate holder.

The burl arrangement may form a pattern and/or may have a periodic arrangement. The burl arrangement can be regular or can vary as desired to provide appropriate distribution of force on the substrate W and/or substrate table WT. The burls can have any shape in plan but are commonly circular in plan. The burls can have the same shape and dimensions throughout their height but are commonly tapered. The distance that the burls project is from the rest of the surface of the main body 100a of the substrate holder 100 and is from about 1 μm to about 5 mm, desirably from about 5 μm to about 250 μm, from the rest of the surface of the main body 100a of the substrate holder 100. The thickness of the main body 100a of the substrate holder 100 can be in the range of about 1 mm to about 50 mm, desirably in the range of about 5 mm to 20 mm, typically 10 mm.

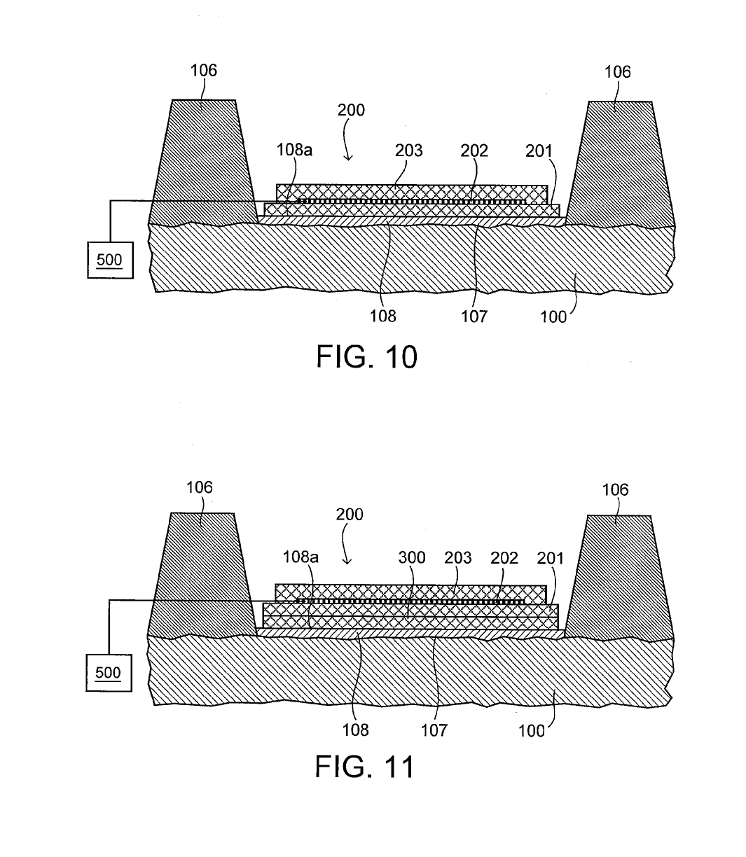

FIG. 10 is an enlargement of part of the substrate holder 100 of FIG. 9 showing the upper surface 107 and some burls 106 in cross-section. A planarization layer 108 is provided on the upper surface 107 in at least some areas between the burls 106. In an embodiment, the planarization layer 108 can be provided only where an electronic component is to be formed or across substantially the entire upper surface of the substrate holder 100. The planarization layer 108 fills in roughnesses of the upper surface 107 and provides an upper surface 108a that is substantially smoother than the surface 107. In an embodiment, the roughness Ra of the surface of the planarization layer 108 is less than about 1.5 μm, desirably less than about 1 μm, or desirably less than about 0.5 μm. In an embodiment, a roughness Ra of the surface of the planarization layer 108 of less than 0.2 μm is achieved by polishing the planarization layer 108 in between the burls after curing.

In an embodiment, the planarization layer 108 is formed by applying a plurality, e.g. two, layers of coating material or precursor material. In an embodiment, the planarization layer 108 may be formed by applying a single layer of coating material or precursor material. Depending upon the material of the planarization layer it may be possible to determine from inspection of the formed coating that it has been applied by forming multiple sub-layers. In an embodiment, the multiple sub-layers of the planarization layer 108 are formed of the same material. In an embodiment, the multiple sub-layers of the planarization layer 108 are formed of different materials. Suitable materials are discussed below.

In an embodiment, the planarization layer 108 is formed of a silicon oxide or silicon nitride-based compound with a functional group attached to each Si atom. The functional group can be at least one selected from the group of hydrogen, methyl, fluoro, vinyl and/or the like. In an embodiment, the planarization layer 108 is formed of Si(CH₃)₂Oₓ. In an embodiment the planarization layer is formed of SiOx, e.g. SiO₂. In an embodiment the planarization layer is formed of benzocyclobutene (BCB). In an embodiment the planarization layer is formed of a polyimide coating material. A method of applying such a material is described in U.S. Pat. No. 7,524,735, which document is incorporated herein in its entirety by reference. In an embodiment the planarization layer 108 is formed of polymer chains consisting of Si(CH₃)₂N and Si(CH₃)₂O backbones.

The planarization layer 108 may have a thickness in the range of from about 0.2 μm to about 200 μm, desirably from about 2 μm to about 30 μm. The planarization layer 108 is desirably sufficiently thick to fill-in most or all of the roughnesses of the surface of the substrate holder. If the planarization layer 108 is too thick, it is more likely to crack during curing. Applying the planarization layer 108 in a plurality of separate coats, as described for example in U.S. patent application No. 61/477,056 filed 19 Apr. 2011 which is hereby incorporated by reference in its entirety, can reduce the chance of such cracking and reduce the surface roughness of the final layer.

In an embodiment, the planarization layer 108 is applied by coating the substrate holder 100 with a polysilazane solution which is then cured to form the silicon-based planarization layer. The reaction involved is shown in U.S. 61/477,056. In an embodiment, the polysilazane solution is applied by a spray technique. Additionally or alternatively, one or more other techniques such as deposition and/or spin coating can be used. In an embodiment, a reaction that proceeds via an aqueous medium alone can be used. In an embodiment, a reaction that proceeds in an aqueous medium in the presence of heat can be used. In each of the reactions, one or more functional groups selected from hydrogen, methyl, and/or fluoro can be present, as described in U.S. 61/477,056.

The planarization layer may be formed in accordance as disclosed in U.S. patent application No. 61/547,600 filed 14 Oct. 2011 hereby incorporated in its entirety by reference.

The planarization layer 108 provides a surface that is sufficiently smooth for reliable formation of a metal or other layer to form a thin film component. In particular, a glass bonding step that may be required with some materials used to form a substrate holder may be unnecessary.

In the substrate holder of FIG. 10, a thin-film stack 200 is formed on the surface 107 of the main body 100 of the substrate holder. The thin film stack 200 comprises the planarization layer 108, a first isolation layer 201, an electrode layer 202 and a second isolation layer 203. A voltage source 500 applies a potential, e.g. in the range of 10 to 5,000 V to the electrode layer 202. The main body 100 is grounded, as are the burls 106 and the substrate. The electric field generated by the potential applied to the electrode layer 202 causes an electrostatic force to clamp the substrate W to the substrate holder.

In an embodiment the electrode layer 202 may be divided into two (or more) electrically separate parts. The voltage source applies a potential difference, e.g. in the range of 10 to 5,000 V, between two parts of the electrode layer 202. One of the parts of the electrode layer 202 is grounded. The resulting field generates an electrostatic clamping force in a similar manner.

One or more sensors and any associated burls are desirably arranged to as to minimize pickup of electromagnetic interference, as described in corresponding U.S. patent application No. 61/576,627, filed on 16 Dec. 2011, which document is incorporated by reference in its entirety.

A difficulty of using a thin film stack including a planarization layer 108 is that the thin films can suffer from defects. Protruding projections in the rough surface 107 of the main body 100 can protrude into the thin film stack. It can be difficult fully to wet the edges of the protruding projections with the planarization layer 108. This can result in the isolation layer 201 above the protruding projections of the rough surface being relatively thin compared to other areas. As a result, when the electrode 201 has a charge applied, particularly a large charge such as in an electrostatic clamp application, at a region surrounding a protruding projection of the rough surface a high charge concentration center can be generated. This is a difficulty when the material of the main body 100 is electrically conductive. Such a high charge concentration center can lead to a leakage current of the order of more than a few pA across the isolation layer 201. This can damage the isolation layer 201.

Polishing may not be effective to remove all of the protruding projections.

In an embodiment, the above mentioned difficulty is addressed by providing a conductive layer in the thin film stack 200. The conductive layer is configured to distribute electrical charge substantially uniformly throughout a plane of the stack in which the conductive layer is positioned.

FIGS. 10-13 illustrate, in cross-section, embodiments of a thin film stack incorporating a conductive layer. The conductive layer works by distributing the electrical charge across a large area, desirably throughout the plane of the conductive layer. The charge would otherwise be concentrated at the position of a protruding projection of the roughed surface.

In an embodiment the conductive layer is, in plan, unpatterned. It may be impossible to predict where a protruding projection of the main body 100 will be present. Therefore, it is desirable not to pattern the conductive layer to increase the chance of all of the potential problematic protruding projections being covered by the conductive layer. In an embodiment the conductive layer extends substantially over the whole area, in plan, of the stack 200.

The embodiment of FIG. 10 illustrates a thin film stack 200 comprising a planarization layer 108, a first isolation layer 201 on the planarization layer 108, a first electrode 202 and a second isolation layer 203 covering the first electrode 202. The second isolation layer includes side edges of the first electrode 202. The conductive layer 108 and electrode layer 202 are separated by an isolation layer, namely the first isolation layer 201.

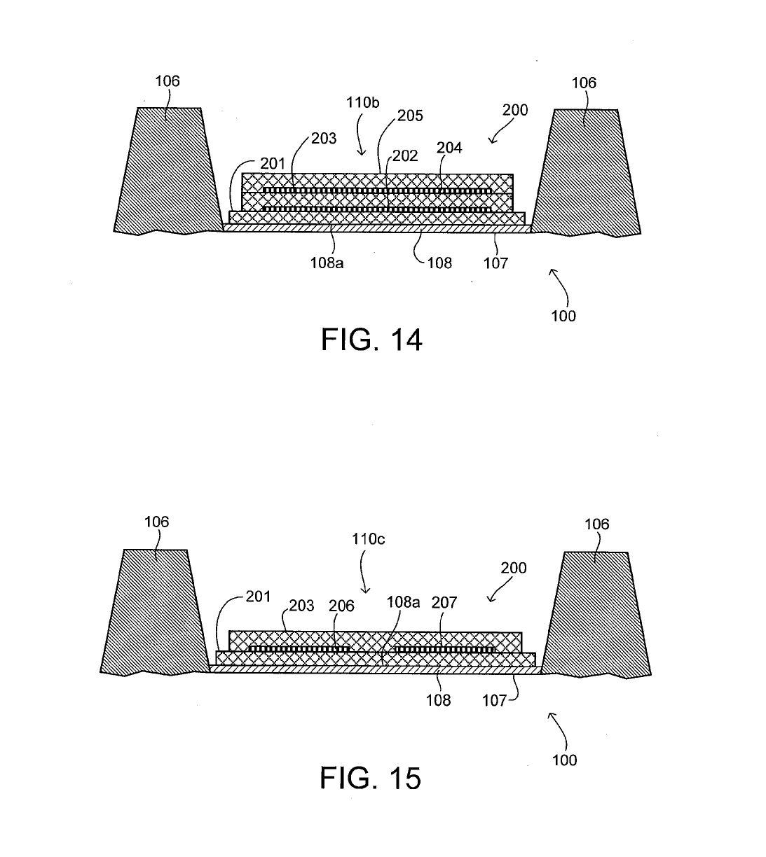

The electrode 202 is, in an embodiment, patterned, in plan. The electrode 202 may form an electrode of an electrostatic clamp and/or may form part of a heater or sensor, as described elsewhere. Although the embodiments of FIGS. 10-13 only show one layer of electrode 202, more than one layer of electrode may be provided, such as illustrated in FIG. 14.

The planarization layer 108 is a conductive planarization layer. Therefore, a charge concentration which could otherwise be present due to a protruding projection from the main body 100 extending to the first isolation layer 201 can be distributed throughout the whole planarization layer 108, in plan.

The planarization layer 108 may be a planarization layer 108 as described above except that it is electrically conductive. This could be achieved, for example, by adding a conductive additive, such as silver particles. An emulsion of the planarization layer could be formed and then sprayed onto the surface of the main body 100, for example. The planarization layer 108, because it is in contact with the main body 100, is electrically connected to the main body 100 which is connected to ground.

As shown in FIG. 10, deposition of different layers forming a thin-film stack 200 on an SiSiC surface of a substrate holder 100 between the burls 106 is possible. The layers follow the general order viz. 1) planarization layer 108, 2) first isolation layer 201 (if necessary), 3) electrode layer 202 (e.g. in the form of metal lines), and 4) a second (top) isolation layer 203. The thin layer stack can be formed on a substrate holder formed of one or more other materials (as described above) or a substrate table formed of one or more similar materials.

The planarization layer 108 is in general as described above but other forms of layer and methods of forming the layer can be used. The planarization layer in an embodiment has a thickness greater than 10 μm. A SiSiC substrate holder has a rough surface (with high Ra of approximately 4 μm and peak to valleys of approximately 43 μm) between the burls. Such roughness may not allow patterning of thin metal electrode lines (e.g., thickness of 20 to 200 nm). To reduce the roughness, polymer dissolved in a suitable solvent is sprayed on the rough SiSiC surface. The liquid layer fills up the valleys present on the EDM finished rough SiSiC between the burls. The liquid is cured to evaporate the solvent and form a smooth polymer layer or planarization layer 108. Metal electrode lines can be patterned on such a planarized surface. If the planarization layer is sufficiently thick and covers all the sharp SiSiC peaks, it may also provide electrical isolation between the SiSiC and the patterned metal electrode lines. The planarization layer can be sprayed all at once or built in a stack by repeating the cycle of spraying a thin layer, curing and spraying a next layer and so on until the desired layer thickness is achieved. A planarization layer may consist of sprayed layers of BCB (40% bis-benzocyclobutene dissolved in 1,3,5-trimethyl benzene) alone or in combination with sprayed layers of NN 120 (20% perhydropolysilazane in di-butyl ether).

The planarization layer 108 is suitable for facilitating the metal electrode patterning, but may not cover all the SiSiC peaks. A thin layer (isolation layer) of PE CVD (Plasma Enhanced Chemical Vapor Deposition) SiOₓ can be deposited on top of the planarization layer to provide electrical isolation between the SiSiC peaks and metal electrode lines if necessary. If the electrical isolation provided by isolation layer is not sufficient, a planarization layer may be sandwiched between two isolation layers and the stack follows the sequence of first isolation layer (PE CVD SiOₓ), then planarization layer and second isolation layer (PE CVD SiOₓ). The isolation layer 201 desirably has a thickness greater than 0.1 μm. Desirably it has a thickness less than 10 μm. In an embodiment the isolation layer has a thickness of 5 μm.

On top of the isolation layer, one or more metal lines 202 are deposited by photolithography or metal deposition and etching through a hard mask. Metal line 202 desirably has a width greater than 20 μm. The maximum width of the metal line is determined by its function and available space. Other methods of forming the metal line are usable. In the case of a heater and/or sensor, one or more wide metal lines (e.g. about 1500 μm) can be used as a heating element and a narrow metal line (e.g. about 100 μm) can be used as a sensor element. For an electrostatic clamp, two halves of continuous metal film (but isolated from the burl tops) separated by approximately 500 μm from each other can be deposited to form positive and negative elements of the electrostatic clamp. Metal line 202 desirably has a layer thickness greater than about 20 nm, desirably greater than about 40 nm. Metal line 202 desirably has a layer thickness less than or equal to about 1 μm, desirably less than about 500 nm, desirably less than about 200 nm.

For a heater and/or sensor, a patterned metal line 202 can have multiple metal layers, for example titanium (Ti) and platinum (Pt). In an embodiment a layer of 10 nm thick titanium provides improved adhesion for a platinum line of approximately 250 thickness. Patterning of multiple layers can be achieved using a combination of photo-resist deposition, PVD for metal film deposition and a lift-off process. For a heater, a wide chromium line (˜1500 μm) can be deposited by Cr film deposition (PVD) and selective Cr etching using a mask. For an electrostatic clamp, an electrode can consist of aluminum, chromium or any other conductive material. An electrode can be formed by PVD or sputtering. An alloy of these metals in any suitable combination can be used.

It is desirable to electrically isolate a deposited metal line from above and protect it from particle deposition, scratches and oxidation. Hence a top or outermost isolation layer is deposited on the metal line 202. For a heater or a sensor, the isolation layer can be deposited by spray coating of BCB (40% bis-benzocyclobutene dissolved in 1,3,5-trimethyl benzene) or NN 120 (20% perhydropolysilazane in di-butyl ether); SiOₓ as described previously; or a combination of sprayed layers and SiOₓ. In the case of an electrostatic clamp, a top isolation layer also provides dielectric strength so that the clamping pressure and gap between the layer stack and substrate can be tuned to desired values. In an embodiment, the top isolation layer for an electrostatic clamp has, or consists of, spray coated polymer layers of BCB, NN 120 (or combination of these two sprayed materials), SiOₓ alone, a combination of one or more spray coated polymer layers and SiOₓ, or parylene (CVD) alone. The top isolation layer 203 desirably has a layer thickness greater than about 0.1 μm, desirably greater than about 1 μm. The top isolation layer 203 desirably has a layer thickness less than about 10 μm, desirably less than about 3 μm, for a heater or a sensor. For an electrostatic clamp, the top isolation layer desirably has a layer thickness less than about 100 μm, desirably less than about 20 μm. In an embodiment the thickness is in a range from about 10 to about 60 μm.

Table 1 shows an examples of suitable materials per layer in order to build a thin-film stack. Each layer may be formed of one of the listed materials or a combination of two or more materials. Methods of application are indicated in parenthesis.

TABLE 1

| Appl. Layer | 1. Heater only | 2. Sensor & Heater | 3. Clamp |
|---|---|---|---|
| Bottom | BCB (spray) | BCB (spray) | BCB (spray) |
| isolation | CAG 37 (spray) | CAG 37 (spray) | CAG 37 (spray) |
| | NN 120 (spray) | NN 120 (spray) | NN 120 (spray) |
| | SiOx, | SiOx, | SiOx |
| | (PVD/CVD/ | (PVD/CVD/ | (PVD/CVD/ |
| | PECVD/ | PECVD/ | PECVD/ |
| | sputtering) | sputtering) | sputtering) |
| | Polyimide (spray) | Polyimide (spray) | Parylene (CVD) |
| | | | Polyimide (spray) |
| Metal | Chrome | Platinum | Chrome, |
| layer | (PVD/CVD/ | (PVD/CVD/ | Aluminum |
| | sputtering) | sputtering | (PVD/CVD/ |
| | | lift-off) | sputtering) |
| Top | BCB (spray) | BCB (spray) | BCB (spray) |
| isolation | CAG 37 (spray) | CAG 37 (spray) | CAG 37 (spray) |
| | NN 120 (spray) | NN 120 (spray) | NN 120 (spray) |
| | SiOx | SiOx | SiOx |
| | (PVD/CVD/ | (PVD/CVD/ | (PVD/CVD/ |
| | PECVD/ | PECVD/ | PECVD/ |
| | sputtering) | sputtering) | sputtering) |
| | Polyimide (spray) | Polyimide (spray) | Parylene (CVD) |
| | | | Polyimide (spray) |

Table 2 shows examples of specific function and requirements per layer for the applications:

TABLE 2

| Appl. Layer | 1. Heater only | 2. Sensor & Heater | 3. Clamp |
|---|---|---|---|
| Bottom | moderate | high electrical | high dielectric |
| isolation | electrical isolation | isolation (for | strength |
| | low temperature | sensor resolution) | high volume |
| | difference across | low temperature | resistivity |
| | the layer | difference across | low temperature |
| | short response | the layer | difference across |
| | time | short response | the layer |
| | | time | |
| Metal | heater power | sensor sensitivity | high voltage |
| layer | | sensor stability | requirements |
| | | heater power | (electrode layout) |
| Top | encapsulation | encapsulation | high dielectric |
| isolation | | | strength |
| | | | high volume |
| | | | resistivity |
| | | | low temperature |
| | | | difference across |
| | | | the layer |

Thin-film technology offers an overlay improvement and a cost effective solution for heater and/or sensor development. A metal pattern design can be modified easily (by modifying a mask design). If a platinum (Pt) metal layer is used, a titanium adherence layer can first be applied to improve adhesion of the Pt layer. For an electrostatic clamp, any suitable metal having a low resistance can be used.

One or more dielectric layers can be deposited by spray coating, spin coating and/or PE CVD techniques. Spray coating is particularly suitable for depositing a polymer based layer (dissolved in organic solvent) such as a BCB and/or NN 120 layer. But a first sprayed layer may suffer from a surface defect such as a pin-hole (e.g., because of local impurity) and/or a crack (most likely because of stress induced in the layer) if too thick a layer is deposited. It is possible to reduce the effect of surface imperfection by combining different deposition processes. In an embodiment, a layer can be applied using an inkjet or bubblejet printing technique. This allows for local control of the layer thickness, which can be useful to correct for local variation in the surface contour or the surface roughness of the substrate holder. These techniques also enable patterning of a conductive layer using a conductive ink. A combination of different materials and/or layer formation techniques can be desirable as a defect in one layer can be cured by another layer.

The isolation layers 201, 203 may be as described above and may for example be formed from one or more layers. In an embodiment the first isolation layer 201 is comprised of 5 μm SiO₂, a layer of 20 μm BCB and a layer of 5 μm SiO₂. In an embodiment the SiO₂ is applied by PECVD. In an embodiment the second (top) isolation layer 203 may comprise SiO₂ or BCB, for example. In an embodiment the planarization layer 108 has a thickness of 10 μm and comprise BCB, for example.

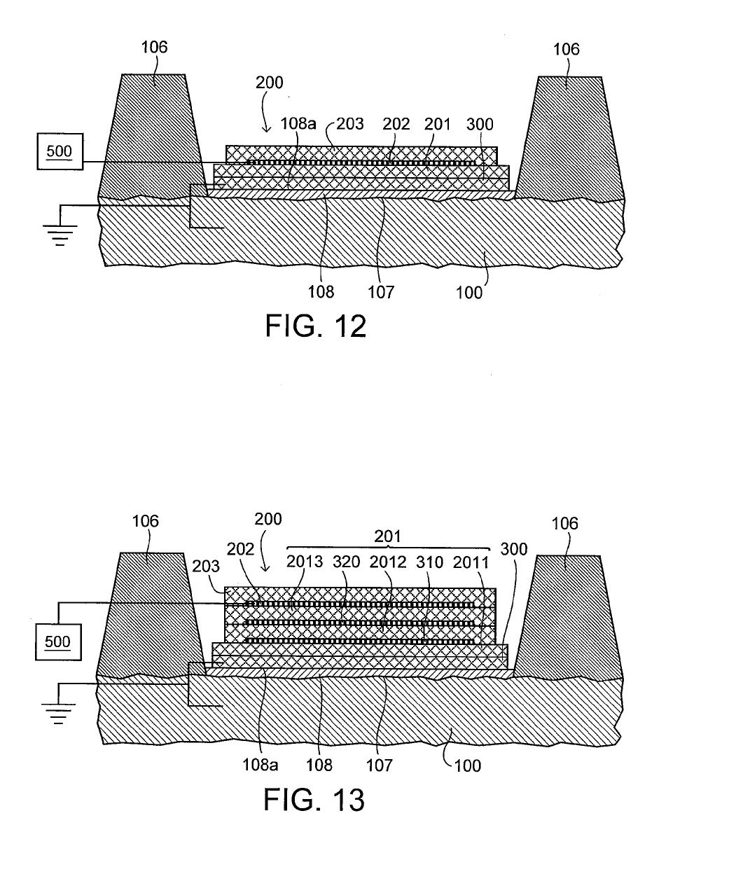

The embodiment of FIG. 11 is the same as that of FIG. 10 except as described below. The planarization layer 108 may or may not be electrically conductive. A conductive layer 300 is provided above the planarization layer 108 and below the first isolation layer 201. The electrically conductive layer 300 may be metal, for example chromium, aluminum, platinum and/or an alloy of two or more of the foregoing metals. In an embodiment the planarization layer 108 is a non-conductive polymer layer (e.g. BCB) of say 10 μm thickness and the conductive layer is a thin metal layer (say 200 nm of chromium). The thin metal layer may or may not be connected to ground together with the main body 100, as in FIG. 12. In an embodiment the conductive layer is between 20 nm and 1 μm thick. Such a thickness of conductive layer is relatively easy to deposit (it is about the same thickness range as the electrode 202) using a thin film technique and is thick enough to distribute the charge uniformly. In an embodiment the conductive layer 300, in the case that the planarization layer 108 is not conductive, is not electrically connected anywhere and is a floating electrode. The floating electrode will distribute the charge substantially uniformly throughout the layer and avoid charge propagation because there will be no concentration of the charge through isolation layer 201. Of course should a protruding projection be present, the floating electrode will distribute a positive charge as an intermediate voltage between the positively charged electrode 202 and the grounded main body 100. The floating electrode of conductive layer 300 may be positioned anywhere within the stack. In an embodiment more than one floating electrode in the form of a conductive layer 300 is present, as described with reference to FIG. 13. For example, one or more floating electrodes may be positioned in between layers comprising the first isolation layer 201.

FIG. 12 illustrates an embodiment which is the same as the embodiment of FIG. 11 except as described below. The conductive layer 300 is electrically connected to the main body 100. Therefore, the electrically conductive layer 300 is connected to ground and operates in the same way as the conductive planarization layer 108 of FIG. 10.

FIG. 13 illustrates an embodiment which is a combination of the embodiments of FIGS. 10-12. Any combination of features may be present. As illustrated in FIG. 13 all of the features are present including a conductive planarization layer 108 and a grounded conductive layer 300. In an embodiment the planarization layer 108 is 10 μm of BCB. The first isolation layer 201 is comprised of three isolation layers 2011, 2012, 2013, for example a first layer 2011 of 5 μm SiO₂, a second layer 2012 of 20 μm BCB and a third layer 2013 of 5 μm BCB. Between the first and second layers 2011 and 2012, a first floating electrode 310 is provided. The floating electrode 310 is the same as the floating electrode 300 of FIG. 11. A second floating electrode 320 is provided between the second and third layers 2012 and 2013 of the first isolation layer 201. In an embodiment, the floating electrodes 310, 320 are encapsulated between their adjacent layers 2011, 2012, 2013. An embodiment of the invention will work as long as one or more of any of the following features is present: the conductive planarization layer 108, the conductive layer 300, the first floating electrode 310 and/or the second floating electrode 302. In an embodiment the grounded conductive layer 300 is not present. In an embodiment the burls 106 are deposited on the body 100 and the body 100 may be of a different material to the burls 106. In this embodiment the body may be sufficiently smooth such that a planarization layer 108 is not required, as disclosed in U.S. patent application no. 61/621,648 filed on 9 Apr. 2012 which is hereby incorporated in its entirety by reference. However, it is possible that at least one floating electrode 310, 320 and/or grounded or non-grounded conductive layer 300 may still be required.

A thin-film stack 110b shown in FIG. 14 is the same as that of FIG. 10 except as described below. The stack 110b comprises, in order above the base layer 100, first isolation layer 201, a first metal layer (e.g., metal lines) 202, second isolation layer 203, second metal layer (e.g., metal lines) 204 and third isolation layer 205. Each of these layers can be formed by a suitable method as described herein. One or more further metal layers and one or more further isolation layers can also be provided. In this embodiment, the use of two or more stacked metal layers allows the formation of two or more stacked components, e.g. sensors. Stacked sensors can provide increased isolation from noise. In an embodiment, one or more metal layers can act as shielding for one or more signal lines in another layer.

A thin-film stack 110c shown in FIG. 15 is the same as that of FIG. 10 except as described below. The stack 110c comprises first isolation layer 201 and second isolation layer 203 either side of the electronic or electric components 206, 207. That is the components are sandwiched between the first and second isolation layers. Multiple components may be formed in a single layer on the substrate. In an embodiment, each of the components 206, 207 is formed by a plurality of layers. For example successive layers of the component may be of metal-amorphous silicon-metal. In such an embodiment, one or more of the components 206, 207 forms a transistor or other logic device. Such logic devices may be used to control an array of heaters disposed across the surface of the substrate holder without requiring individual connections to each heater. The transistors can be arranged at the intersection of word and bit lines and each connected to an associated heater to form an active matrix.

In an embodiment having an electrostatic clamp, the separation between the thin-film electrostatic clamp and the substrate is well controlled and consistent so that the clamping force applied by the electrostatic clamp is more consistent (compared with the force that would be applied if the separation between the electrostatic clamp and a substrate was less well controlled). This is beneficial because non-uniformity in the clamping force applied to the substrate should be avoided. This is because non-uniformity of the clamping force could cause distortion of the substrate.

A so-called pin-hole or crack, such as a break in the crystalline structure of a thin-film known as a dislocation, might arise in a thin-film layer, e.g. an isolation layer of an electrostatic clamp. Such a fault might give rise to reduced performance or failure of a component in the thin-film stack, e.g. poor isolation. In an embodiment, this may be beneficially avoided by providing the isolation layer as several thin layers stacked together, such that a pin-hole or crack in a particular isolation layer is at least partially filled in when the next isolation layer is deposited. The probability of a fault in one layer overlapping a fault in another layer is small.

An electronic or electric component to be formed on the substrate table can include, for example, an electrode, a resistive heater and/or a sensor, such as (in a non-limiting list) a strain sensor, a magnetic sensor, a pressure sensor, a capacitive sensor or a temperature sensor. A heater and sensor can be used to locally control and/or monitor the temperature of the substrate holder and/or substrate so as to reduce undesired, or induce desired, temperature variation and stress in the substrate holder or substrate. Desirably, the heater and sensor are formed on, around and/over the same region as each other. It is desirable to control temperature and/or stress of the substrate in order to reduce or eliminate imaging errors such as overlay errors due to local expansion or contraction of the substrate. For example, in an immersion lithography apparatus, evaporation of residual immersion liquid (e.g., water) on the substrate can cause localized cooling, may apply a heat load to the surface on which the liquid is located, and hence shrinkage of the substrate. Conversely, the energy delivered to the substrate by the projection beam during exposure can cause significant heating and therefore expansion of the substrate.

In an embodiment, the component to be formed is an electrode for an electrostatic clamp. In electrostatic clamping, an electrode provided on the substrate table and/or substrate holder is raised to a high potential, e.g. from 10 to 5,000 V. The substrate can be grounded or floating. Electrostatic forces in the electric field generated by the electrode attract the substrate to the substrate table and/or holder to provide a clamping force. This is described further below.

One or more electrical connections can be provided to connect the electric or electronic component on the substrate holder to a voltage source (not shown for convenience). If the component is an electrostatic clamp, the electrode on the substrate has an electrical connection to the voltage source. The component may be on a top surface of the substrate support. At least part of the electrical connection may pass through the body of the substrate support as described in U.S. patent application No. 61/555,359, filed on 3 Nov. 2011, which is hereby incorporated by reference in its entirety.

In an embodiment, one or more localized heaters 101 are controlled by controller to provide a desired amount of heat to the substrate holder 100 and substrate W to control the temperature of the substrate W. One or more temperature sensors 102 are connected to controller which monitors the temperature of the substrate holder 100 and/or substrate W. Arrangements using one or more heaters and temperature sensors to locally control the temperature of a substrate are described in copending U.S. patent application publication no. 2012-0013865, which document is incorporated herein by reference in its entirety. The arrangements described therein can be modified to make use of a resistive heater and temperature sensor as described herein.

Although specific methods have been described above which may be used to form one or more burls, sensors, heaters and/or electrostatic clamps, in a unitary manner as a multi-layer structure, any other suitable method may be used. In an embodiment of the invention, a thin-film stack is provided on only one side of the substrate holder. In an embodiment, thin-film stacks are provided on both sides of the substrate holder. In an embodiment, burls are provided on both sides of the substrate holder. If burls are provided on a side of the substrate holder that does not have a thin-film stack thereon, any convenient method for forming the burls on that side can be used. Such a method include any one or more of those described above as well as one or more other methods, such as machining that involves removal of material from the main body. Deposition of one or more layers can be achieved by plasma enhanced chemical vapor deposition (PE CVD), chemical vapor deposition (CVD), physical vapor deposition (PVD) and/or sputtering. The method used for the deposition depends upon the material(s) being deposited. The thickness variation obtained by the deposition can be smaller than 5 percent.

A substrate holder for use in a conventional (DUV) lithographic apparatus (e.g. an immersion lithographic apparatus) is desirably provided with one or more thin-film temperature sensors and/or thin-film heaters.

A substrate holder for use in an EUV lithographic apparatus is desirably provided with a thin-film electrostatic clamp and optionally one or more thin-film temperature sensors and/or thin-film heaters.

As will be appreciated, any of the above described features can be used with any other feature and it is not only those combinations explicitly described which are covered in this application. For example, a structure such as that illustrated in FIGS. 14 and 15 and described above could be placed above the planarization layer 108 and/or conductive layer 300 and/or the first isolation layer 201 of any of FIGS. 11-13.

Although specific reference may be made in this text to the use of lithographic apparatus in the manufacture of ICs, it should be understood that the lithographic apparatus described herein may have other applications in manufacturing components with microscale, or even nanoscale features, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of or about 365, 248, 193, 157 or 126 nm).

The term “lens”, where the context allows, may refer to any one or combination of various types of optical components, including refractive and reflective optical components.

While specific embodiments of the invention have been described above, it will be appreciated that the invention, at least in the form of a method of operation of an apparatus as herein described, may be practiced otherwise than as described. For example, the embodiments of the invention, at least in the form of a method of operation of an apparatus, may take the form of one or more computer programs containing one or more sequences of machine-readable instructions describing a method of operating an apparatus as discussed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Any controllers described herein may each or in combination be operable when the one or more computer programs are read by one or more computer processors located within at least one component of the lithographic apparatus. The controllers may each or in combination have any suitable configuration for receiving, processing and sending signals. One or more multiple processors are configured to communicate with at least one of the controllers. For example, each controller may include one or more processors for executing the computer programs that include machine-readable instructions for the methods of operating an apparatus as described above. The controllers may include data storage media for storing such computer programs, and/or hardware to receive such media. So the controller(s) may operate according to the machine readable instructions of one or more computer programs.

An embodiment of the invention may be applied to substrates with a width (e.g., diameter) of 300 mm or 450 mm or any other size.

One or more embodiments of the invention may be applied to any immersion lithography apparatus, in particular, but not exclusively, those types mentioned above, whether the immersion liquid is provided in the form of a bath, only on a localized surface area of the substrate, or is unconfined on the substrate and/or substrate table. In an unconfined arrangement, the immersion liquid may flow over the surface of the substrate and/or substrate table so that substantially the entire uncovered surface of the substrate table and/or substrate is wetted. In such an unconfined immersion system, the liquid supply system may not confine the immersion liquid or it may provide a proportion of immersion liquid confinement, but not substantially complete confinement of the immersion liquid.

A liquid supply system as contemplated herein should be broadly construed. In certain embodiments, it may be a mechanism or combination of structures that provides a liquid to a space between the projection system and the substrate and/or substrate table. It may comprise a combination of one or more structures, one or more liquid inlets, one or more gas inlets, one or more gas outlets, and/or one or more liquid outlets that provide liquid to the space. In an embodiment, a surface of the space may be a portion of the substrate and/or substrate table, or a surface of the space may completely cover a surface of the substrate and/or substrate table, or the space may envelop the substrate and/or substrate table. The liquid supply system may optionally further include one or more elements to control the position, quantity, quality, shape, flow rate or any other features of the liquid.

In first aspect of the invention there is provided a substrate holder for use in a lithographic apparatus. The substrate holder comprises a main body, a plurality of burls and a thin film stack. The main body has a surface. The plurality of burls projects from the surface and have end surfaces to support a substrate. The thin film stack is on the main body surface and forms an electric component, the thin film stack comprising a conductive layer configured to distribute electrical charge substantially uniformly throughout a plane of the stack in which the conductive layer is positioned.

The conductive layer may be, in plan, unpatterned. The conductive layer may extend over substantially the whole area, in plan, of the stack. The conductive layer may be a metal layer. The metal may be at least one metal selected from: Cr, Al, Pt and/or an alloy of two or more of the foregoing metals. The conductive layer may be between 20 nm and 1 μm thick.

The conductive layer may be a planarization layer formed on the main body surface. The planarization layer may comprise a conductive additive. The thin film stack may comprise a planarization layer formed on the main body surface. The planarization layer may have a surface roughness Ra less than about 1.5 μm, less than about 1.0 μm, or less than about 0.5 μm. The planarization layer may be formed of a silicon-based material. The planarization layer may be formed of a silicon oxide or silicon nitride based material. The planarization layer may include at least one functional group selected from the group consisting of hydrogen, methyl, fluoro, vinyl and the like. The planarization layer may comprise at least one material selected from the group consisting of: benzocyclobutene, perhydropolysilazene, SiO₂, parylene, polyimide and/or a combination of two or more of the foregoing.

At least the layer adjacent the conductive layer may be an isolation layer. The conductive layer may be electrically connected to the main body. The conductive layer may be a floating electrode. The thin film stack may further comprise a further conductive layer which is an electrode layer. The electrode layer may be patterned, in plan. The electrode layer and conductive layer may be separated by an isolation layer. The stack further may comprise a top isolation layer provided above the electrode layer. The isolation layer may have a thickness in the range of from about 0.1 μm to about 100 μm. The isolation layer may have a thickness in the range of from about 0.1 μm to about 10 μm, desirably from about 1 μm to about 3 μm. The isolation layer may be formed of at least one material selected from the group consisting of: benzocyclobutene, perhydropolysilazene, SiOₓ, parylene, polyimide and/or a combination of two or more of the foregoing. The isolation layer may have a thickness in the range of from about 20 μm to about 100 μm, desirably from about 40 μm to about 60 μm. The electrode may, in use, be an electrode of an electrostatic clamp.

The main body may be formed of at least one material selected from the group consisting of SiC (silicon carbide), SiSiC (siliconized silicon carbide), Si₃N₄ (silicon nitrite), quartz, and/or Zerodur™.

In a second embodiment of the invention there is provided a lithographic apparatus, comprising: a support structure, a projection system and a substrate holder. The support structure is configured to support a patterning device. The projection system is arranged to project a beam patterned by the patterning device onto a substrate. The substrate holder is arranged to hold the substrate, the substrate holder being according to the first aspect of the invention.

The lithographic apparatus may further comprise a substrate table and wherein the substrate holder is integrated into the substrate table. The apparatus may be an EUV projection apparatus.

In a third aspect of the invention there is provided a device manufacturing method using a lithographic apparatus, the method comprising: projecting a beam patterned by a patterning device onto a substrate while holding the substrate in or on a substrate holder, the substrate holder comprising: a main body having a surface, a plurality of burls projecting from the surface and having end surfaces to support a substrate, and a thin film stack on the main body surface and forming an electric component, the thin film stack comprising a conductive layer configured to distribute electrical charge substantially uniformly throughout a plane of the stack in which the conductive layer is positioned.

In a fourth aspect of the invention there is provided a substrate holder for use in a lithographic apparatus, the substrate holder comprising: a main body having a surface; a plurality of burls projecting from the surface and having end surfaces to support a substrate; and a thin film stack on the main body surface and forming an electric component, the thin film stack comprising a conductive layer which extends over substantially the whole area, in plan, of the stack.

The descriptions above are intended to be illustrative, not limiting. Thus, it will be apparent to one skilled in the art that modifications may be made to the invention as described without departing from the scope of the claims set out below.

1. A substrate holder, the substrate holder comprising:
a main body having a surface;
a plurality of burls projecting from the surface and having end surfaces to support a substrate; and
a thin film stack on the main body surface and forming an electric component, the thin film stack comprising a conductive layer configured to distribute electrical charge substantially uniformly throughout a plane of the stack in which the conductive layer is positioned, wherein the thin film stack comprises a planarization layer formed on the main body surface.

2. The substrate holder of claim 1, wherein the conductive layer is, in plan, unpatterned.

3. The substrate holder of claim 1, wherein the conductive layer extends over substantially the whole area, in plan, of the stack.

4. The substrate holder of claim 1, wherein the conductive layer is a metal layer.

5. The substrate holder of claim 1, wherein the planarization layer comprises the conductive layer.

6. The substrate holder of claim 1, wherein the thin film stack comprises an isolation layer between an electrode layer and the planarization layer.

7. The substrate holder of claim 1, wherein at least a layer adjacent the conductive layer is an isolation layer.

8. The substrate holder of claim 1, wherein the conductive layer is electrically connected to the main body.

9. The substrate holder of claim 1, wherein the conductive layer is a floating electrode.

10. The substrate holder of claim 1, wherein the thin film stack further comprises a further conductive layer which is an electrode layer.

11. The substrate holder of claim 10, wherein the electrode layer and conductive layer are separated by an isolation layer.

12. The substrate holder of claim 11, wherein the electrode is, in use, an electrode of an electrostatic clamp.

13. A lithographic apparatus, comprising:
a support structure configured to support a patterning device;
a projection system arranged to project a beam patterned by the patterning device onto a radiation-sensitive substrate; and
the substrate holder according to claim 1 and arranged to hold the radiation-sensitive substrate.

14. A device manufacturing method using a lithographic apparatus, the method comprising:
projecting a beam patterned by a patterning device onto a substrate while holding the substrate in or on a substrate holder, the substrate holder comprising:
a main body having a surface,
a plurality of burls projecting from the surface and having end surfaces to support a substrate, and
a thin film stack on the main body surface and forming an electric component, the thin film stack comprising a conductive layer configured to distribute electrical charge substantially uniformly throughout a plane of the stack in which the conductive layer is positioned, wherein the thin film stack comprises a planarization layer formed on the main body surface so that the roughness of the main body surface is filled in by the planarization layer so as to provide a substantially smoother surface than the surface of the main body and for reliable formation of a metal or other layer to form a thin film component.

15. A substrate holder for use in a lithographic apparatus, the substrate holder comprising:
a main body having a surface;
a plurality of burls projecting from the surface and having end surfaces to support a substrate; and
a thin film stack on the main body surface and forming an electric component, the thin film stack comprising a conductive layer which extends over substantially the whole area, in plan, of the stack wherein the thin film stack comprises a planarization layer formed on the main body surface.

16. The substrate holder of claim 15, wherein the planarization layer comprises the conductive layer.

17. The substrate holder of claim 15, wherein the thin film stack comprises an isolation layer between an electrode layer and the planarization layer.

18. The substrate holder of claim 15, wherein at least a layer adjacent the conductive layer is an isolation layer.

19. The substrate holder of claim 15, wherein the conductive layer is a floating electrode.

20. The substrate holder of claim 15, wherein the thin film stack further comprises a further conductive layer which is an electrode layer.
